(19) United States
(12) Patent Application Publication
(10) Pub. No.: US 2026/0017437 A1
(43) Pub. Date: Jan. 15, 2026

(54) COMPUTER PROGRAM, INFORMATION PROCESSING METHOD, AND INFORMATION PROCESSING DEVICE

(71) Applicant: Tokyo Electron Limited, Tokyo (JP)

(72) Inventors: Daiki KAWAHITO, Sapporo City (JP); Yusuke OGAWA, Sapporo City (JP); Hironori MOKI, Miyagi (JP); Takuro TSUTSUI, Sapporo City (JP)

(73) Assignee: Tokyo Electron Limited, Tokyo (JP)

(21) Appl. No.: 19/335,013

(22) Filed: Sep. 22, 2025

Related U.S. Application Data
(63) Continuation of application No. PCT/JP2024/011072, filed on Mar. 21, 2024.

(30) Foreign Application Priority Data
Mar. 30, 2023 (JP) 2023-056045

(51) Int. Cl. G06F 30/27

(52) U.S. Cl. CPC G06F 30/27

(57) ABSTRACT

Using a simulation model that simulates substrate processing using a plurality of parameters related to a condition of the substrate processing, or a trained model that outputs a predicted shape of a substrate after processing according to inputs of the plurality of parameters and an initial shape of the substrate, the plurality of parameters are adjusted such that the predicted shape becomes a specific shape. A predicted shape is acquired by simulating the substrate processing by the simulation model using the plurality of parameters after the adjustment and a specific initial shape of the substrate and using the trained model according to the plurality of parameters after the adjustment and the specific initial shape. An error between the predicted shape acquired by the simulation model and the predicted shape acquired using the trained model is calculated. Accuracy of the prediction using the trained model is determined based on the error.

### CROSS-REFERENCE TO RELATED APPLICATIONS

This application is a bypass continuation application of international application No. PCT/JP2024/011072 having an international filing date of Mar. 21, 2024 and designating the United States, the international application being based upon and claiming the benefit of priority from Japanese Patent Application No. 2023-056045, filed on Mar. 30, 2023, the entire contents of which are incorporated herein by reference.

### TECHNICAL FIELD

The present disclosure relates to a computer program, an information processing method, and an information processing device.

### BACKGROUND

Substrate processing for performing processing such as etching or film formation on a substrate such as a semiconductor wafer or a glass substrate is performed according to a recipe defining processing contents. In the related art, a shape simulation has been performed using a computer to calculate a predicted shape that is a shape obtained by predicting a shape of a substrate after substrate processing. In the shape simulation, substrate processing is simulated using a plurality of processing parameters related to the substrate processing according to recipes. Further, a recipe for obtaining a specific substrate is searched for by adjusting processing parameters such that a specific predicted shape can be obtained through the shape simulation. PTL 1 discloses an example of a technique for performing a shape simulation.

### CITATION LIST

### Patent Documents

PTL 1: JP6890632B

### SUMMARY

As a technique of replacing or supplementing the shape simulation, there is a technique using a trained model that is trained to output a predicted shape when an initial shape and processing parameters of a substrate are input. However, the accuracy of prediction of the shape of the substrate using the trained model may differ from the accuracy of prediction by a shape simulation.

The present disclosure provides a non-transitory computer readable medium (e.g., computer program), an information processing method, and an information processing device for evaluating prediction accuracy using a trained model. By integrating the evaluation and improvement of the trained model's prediction accuracy into the substrate manufacturing process, the method provides a practical application where the retrained model is used to optimize processing parameters, such as gas flow rates, voltage, and pressure, for controlling a substrate processing apparatus. This optimization enables precise control of etching or film formation, reducing manufacturing defects, improving yield in semiconductor production, and allowing real-time adjustments to recipes based on predicted shapes that reflect physical effects like temperature or electric fields, thereby enhancing the efficiency and reliability of high-volume substrate fabrication.

A non-transitory computer readable medium according to an aspect of the present disclosure stores a computer program that, when executed by a computer, causes the computer to execute a method comprising adjusting, by using a simulation model that simulates substrate processing using a plurality of parameters related to a condition of the substrate processing, or a trained model that outputs a predicted shape obtained by predicting a shape of a substrate after processing according to inputs of the plurality of parameters and an initial shape of the substrate, the plurality of parameters such that the predicted shape becomes a specific shape, acquiring a predicted shape by simulating the substrate processing by the simulation model using the plurality of parameters after the adjustment and a specific initial shape of the substrate, acquiring a predicted shape using the trained model according to the plurality of parameters after the adjustment and the specific initial shape, calculating an error between the predicted shape acquired by the simulation model and the predicted shape acquired using the trained model, and determining accuracy of the prediction using the trained model based on the error.

According to the present disclosure, a computer program, an information processing method, and an information processing device for evaluating prediction accuracy using a trained model can be provided.

### BRIEF DESCRIPTION OF DRAWINGS

FIG. 1 is a block diagram illustrating an example of an internal configuration of an information processing device;

FIG. 2 is a conceptual diagram illustrating an example of contents of training data;

FIG. 3 is a conceptual diagram illustrating an example of a plurality of processing parameters;

FIG. 4 is a flowchart illustrating an example of a procedure of information processing executed by the information processing device;

FIG. 5 is a flowchart illustrating an example of a procedure of the information processing executed by the information processing device;

FIG. 6 is a flowchart illustrating an example of a procedure of the information processing executed by the information processing device;

FIG. 7 is a conceptual diagram illustrating an example of contents of an error database; and

FIG. 8 is a conceptual diagram illustrating an example of contents of a model database.

### DETAILED DESCRIPTION

Hereinafter, the disclosure will be specifically described with reference to the drawings illustrating an embodiment thereof.

A process for producing a substrate such as a semiconductor wafer, a glass substrate, or a flat panel substrate includes a process of performing substrate processing such as etching or film formation on a substrate. Hereinafter, an apparatus for executing substrate processing will be referred to as a processing apparatus. For example, the processing apparatus includes a process chamber, and performs the substrate processing, such as etching, on a substrate disposed in the process chamber. The processing apparatus processes the substrate according to a predetermined recipe that defines contents of the substrate processing. The substrate processing is performed under processing conditions defined in the recipe. The processing conditions include a shape of the process chamber, a flow rate of the supplied gas, the supplied power, the pressure, and the temperature. The shape of the substrate after the substrate processing is predicted by performing the shape simulation using processing parameters related to processing conditions. Further, the shape of the substrate after the substrate processing can be predicted by using the trained model. In the present embodiment, the prediction results obtained by a shape simulation and the prediction results obtained using the trained model are compared with each other, and the accuracy of prediction using the trained model is evaluated.

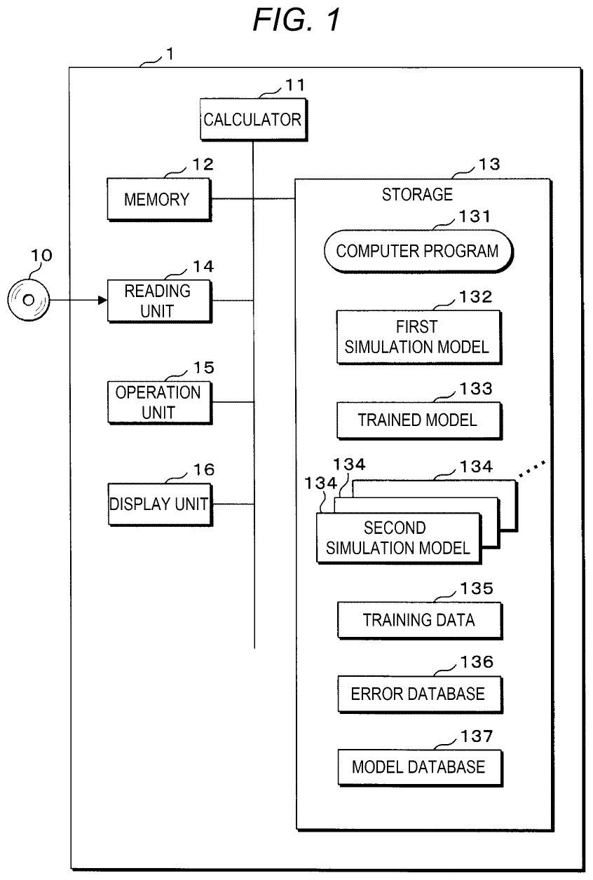

FIG. 1 is a block diagram illustrating an example of an internal configuration of an information processing device 1. The information processing device 1 executes an information processing method. The information processing device 1 is implemented using a computer such as a personal computer or a server device. The information processing device 1 includes a calculator 11, a memory 12, a storage 13, a reading unit 14, an operation unit 15, and a display unit 16. The calculator 11 is implemented using, for example, a central processing unit (CPU), a graphics processing unit (GPU), or a multi-core CPU. The calculator 11 may also be implemented using a quantum computer. The memory 12 stores temporary data generated along with calculation. The memory 12 is, for example, a random access memory (RAM). The storage 13 is non-volatile, and is, for example, a hard disk or a non-volatile semiconductor memory. The reading unit 14 reads information from a recording medium 10 such as an optical disc or a portable memory. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The operation unit 15 receives an input of information such as text by receiving an operation from a user. The operation unit 15 is, for example, a keyboard, a pointing device, or a touch panel. The display unit 16 displays an image. The display unit 16 is, for example, a liquid crystal display or an electroluminescent display (EL display). The operation unit 15 and the display unit 16 may be integrated.

The calculator 11 causes the reading unit 14 to read a computer program (program product) 131 recorded in the recording medium 10, and causes the storage 13 to store the read computer program 131. The calculator 11 executes processing for implementing functions of the information processing device 1 according to the computer program 131. The computer program 131 may be stored in advance in the storage 13 or may be downloaded from outside the information processing device 1. In this case, the information processing device 1 does not need to be provided with the reading unit 14.

The computer program 131 may be loaded to be executed on a single computer or on a plurality of computers disposed at one site or distributed across a plurality of sites and interconnected by a communication network. That is, the information processing device 1 may be implemented by a plurality of computers, and the computer program 131 may be executed on the plurality of computers connected via the communication network. The information processing device 1 may be implemented using a cloud server.

The information processing device 1 includes a first simulation model 132 that performs a shape simulation for predicting a shape of a substrate obtained by substrate processing. The first simulation model 132 simulates substrate processing performed on a substrate having any shape under any processing conditions. The first simulation model 132 performs a simulation using a plurality of processing parameters related to processing conditions, and calculates a predicted shape obtained by predicting a shape of the substrate after the substrate processing. The first simulation model 132 includes a computer program for the shape simulation. The computer program for executing a shape simulation is stored in the storage 13 and included in, for example, the computer program 131.

Further, the information processing device 1 includes a trained model 133 that outputs a predicted shape of the substrate when the shape of the substrate and a plurality of processing parameters are input. The trained model 133 is trained in advance to output the predicted shape when initial shapes, which are shapes of substrates before substrate processing, and a plurality of processing parameters are input. The trained model 133 is implemented by executing information processing by the calculator 11 according to the computer program 131. For example, the trained model 133 is implemented by using a neural network.

The trained model 133 may be configured with hardware. For example, the trained model 133 may be configured with hardware that includes a processor and a memory storing necessary programs and data. Alternatively, the trained model 133 may be implemented by using a quantum computer. Alternatively, the trained model 133 may be provided outside the information processing device 1, and the information processing device 1 may execute processing using the external trained model 133. For example, the trained model 133 may be implemented using a cloud.

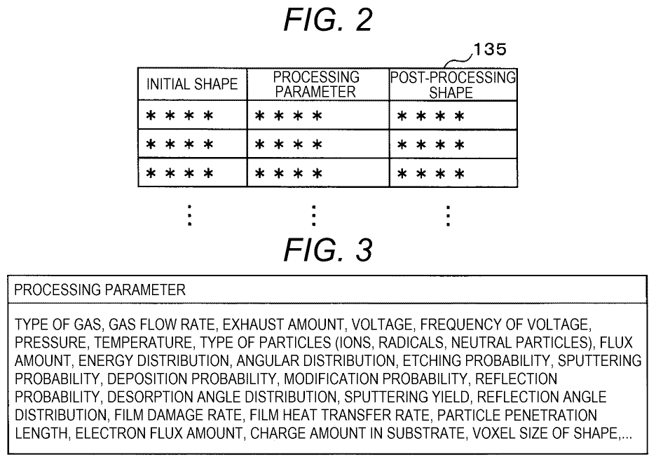

Training data 135 used for training the trained model 133 is stored in the storage 13. FIG. 2 is a conceptual diagram illustrating an example of contents of the training data 135. In the training data 135, the initial shape of a substrate, a value of a processing parameter, and a post-processing shape of a substrate are recorded in association with each other. The training data 135 includes a large number of data sets each having an initial shape, a value of a processing parameter, and a predicted shape associated therewith.

The initial shape is data representing a shape of a substrate before the substrate processing is performed, and the post-processing shape is data representing a shape of a substrate after the substrate processing. The initial shape and the post-processing shape may be images representing the shape of the substrate, such as a cross-sectional view of the substrate. The initial shape and the post-processing shape may include features indicating a size or a physical structure of the substrate. The size of the substrate may include a vertical size, a lateral size, or a height size of the substrate, or a size of a specific portion of the substrate. The feature indicating a physical structure is, for example, a critical dimension (CD) value of a pattern formed on a substrate or an aspect ratio of a groove formed on a substrate.

FIG. 3 is a conceptual diagram illustrating an example of a plurality of processing parameters. The plurality of processing parameters relate to processing conditions for substrate processing, and each processing parameter defines a corresponding element of the processing condition. The processing parameters may include the type of a gas to be supplied to a processing apparatus for performing substrate processing, a flow rate of the gas, an exhaust amount of the gas, a voltage supplied for the substrate processing in the processing apparatus, frequencies of the voltage, and a pressure and temperature in the process chamber. The processing parameters may include the types of particles, such as ions, radicals, and neutral particles incident on the substrate during the substrate processing, and the flux amount indicating the number of each type of particle incident on the unit area of a surface of the substrate per unit time. The processing parameters may include an energy distribution of each type of particle incident on the surface of the substrate, and a distribution of angles at which each type of particle is incident on the surface of the substrate.

The processing parameters may include an etching probability, which is a probability that the surface of the substrate is etched by particles originating from plasma during the substrate processing using plasma, such as plasma etching, and a sputtering probability, which is a probability that the surface of the substrate is sputtered by the particles. The processing parameters may include a deposition probability, which is a probability that the particles deposit on the surface of the substrate, a modification probability, which is a probability that the substance on the surface of the substrate changes due to an interaction with the particles, and a reflection probability, which is a probability that the particles are reflected by the surface of the substrate. The processing parameters may include a desorption angle distribution, which is an angular distribution of the particles desorbed from the surface of the substrate by sputtering, and a sputtering yield, which is an amount of the desorbed substance that depends on an incidence angle of the particles during the sputtering.

The processing parameters may include a reflection angle distribution, which is an angular distribution of particles reflected by the surface of the substrate, a film damage rate, which is a defect rate due to an interaction of films on the surface of the substrate, a film heat transfer rate, which is a thermal conductivity of the film on the substrate, and a film penetration length, which is a distance by which the particles penetrate into the film on the substrate through the interaction. The processing parameters may include an electron flux amount indicating the number of electrons incident on the surface of the substrate, an amount of charges in the substrate, which is an amount of charges charged to the substrate by the incidence of particles, and a Voxel size used to represent the shape of the substrate.

The trained model 133 is generated by performing machine learning using the training data 135 in a learning apparatus using a computer. In the machine learning, the learning apparatus inputs initial shapes and processing parameters recorded in the training data 135 to a model serving as an element of the trained model 133, and the model performs calculations according to the inputs of the initial shapes and the processing parameters and outputs a predicted shape. The learning apparatus adjusts parameters of the calculation of the model so as to reduce an error between the predicted shape output by the model and the post-processing shape associated with the input initial shape and the input processing parameters. For example, the adjustment of the parameters is performed by an error back propagation method.

The learning apparatus performs machine learning by repeating processing using a plurality of data sets included in the training data and adjusting the parameters of the model. The trained model 133 is generated by adjusting the parameters of the calculation in this way. For example, the adjusted final parameters are input to the information processing device 1 and stored in the storage 13, and the calculator 11 executes information processing using the parameters, so that the trained model 133 is implemented. The learning apparatus may be the information processing device 1.

The information processing device 1 includes a second simulation model 134 including specific additional mechanisms that are not included in the first simulation model 132. Similar to the first simulation model 132, the second simulation model 134 performs a shape simulation that predicts the shape of the substrate obtained by the substrate processing, using a plurality of processing parameters. An additional function included in the second simulation model 134 is a function that reflects specific physical effects, which are not considered in the first simulation model 132 in the shape simulation, in the predicted shape.

The additional function is, for example, a function of calculating a physical influence on a predicted shape caused by an electric external field in a vicinity of a substrate. The additional function is, for example, a function of calculating a physical influence of the damage to the film on the surface of the substrate on the predicted shape. The additional function is, for example, a function of calculating a physical influence on a predicted shape caused by dependence of by-products during substrate processing. The additional function is, for example, a function of calculating a physical influence on a predicted shape caused by a temperature effect. The additional function is, for example, a function of calculating a physical influence on a predicted shape caused by particles incident on the substrate diffusing or entering the inside of the substrate.

The second simulation model 134 includes a computer program for a shape simulation including an additional function. The computer program for a shape simulation including an additional function is stored in the storage 13 and included in, for example, the computer program 131. The information processing device 1 includes a plurality of second simulation models 134 each having an additional function different from each other.

The storage 13 stores an error database 136 and a model database 137. The error database 136 is a database for recording data related to the calculation of a predicted shape when an error between a predicted shape obtained by the first simulation model 132 and a predicted shape obtained by the trained model 133 is large. The model database 137 is a database for recording data related to an error between the predicted shape obtained by the first simulation model 132 and a predicted shape obtained by the second simulation model 134. The error database 136 and the model database 137 will be described in detail later.

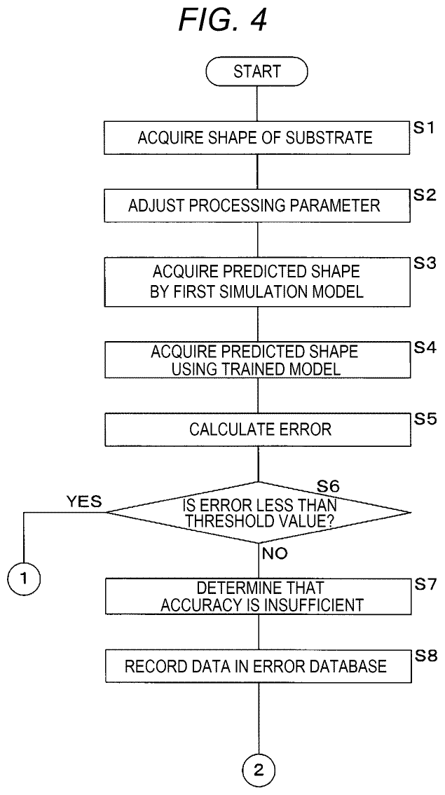

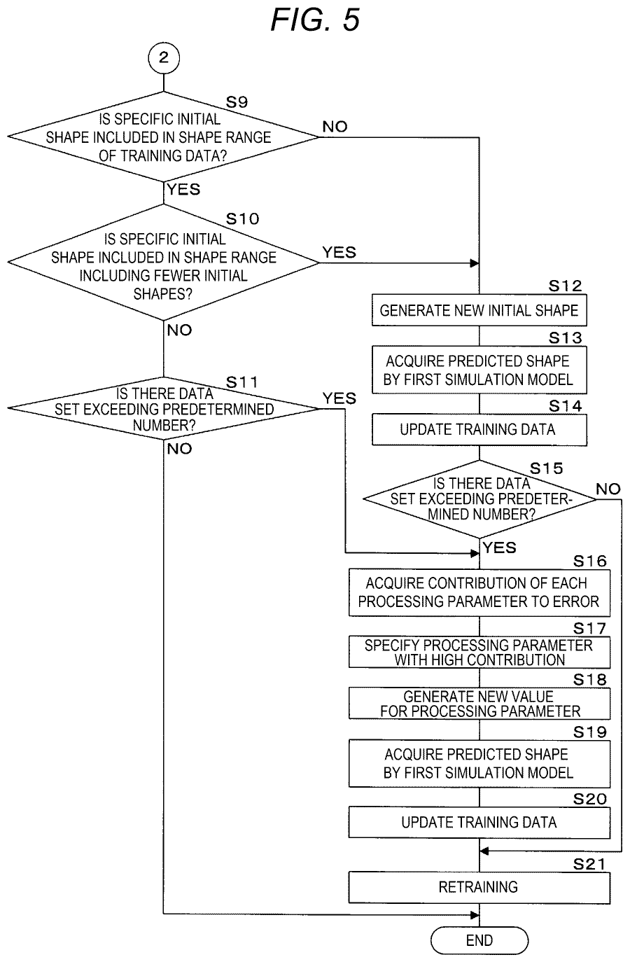

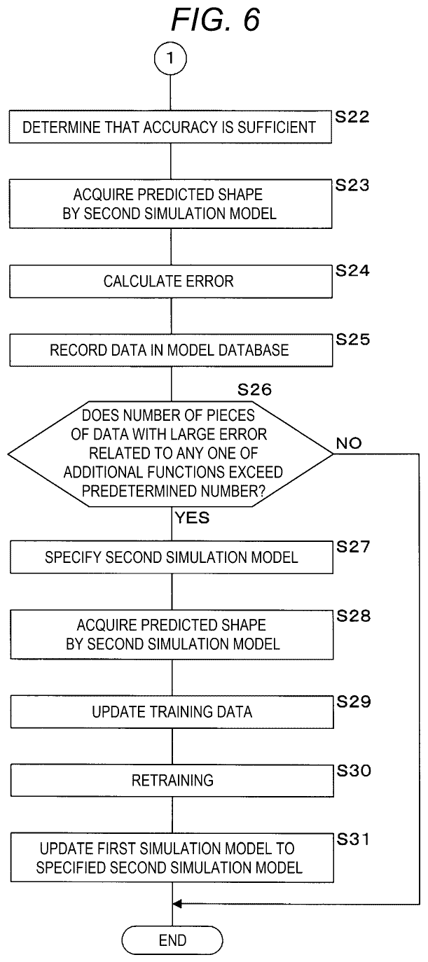

The information processing executed by the information processing device 1 will be described. FIGS. 4 to 6 are flowcharts illustrating an example of a procedure of information processing executed by the information processing device 1. Hereinafter, the step of the information processing executed by the information processing device 1 will be abbreviated as S. The information processing device 1 executes the following processing by the calculator 11 executing the information processing according to the computer program 131.

The information processing device 1 acquires the shape of the substrate (S1). The shape of the substrate includes a specific initial shape of the substrate and a specific post-processing shape of the substrate. In S1, the calculator 11 reads data representing the shape of the substrate stored in advance in the storage 13, thereby acquiring a specific shape of the substrate. The calculator 11 may perform information processing for generating a shape of a substrate. In S1, the shape of the substrate may be input from an outside of the information processing device 1 into the information processing device 1. For example, the shape of the substrate may be input into the information processing device 1 by the user operating the operation unit 15.

Next, the information processing device 1 adjusts a plurality of processing parameters related to the processing conditions of the substrate processing, using the first simulation model 132 or the trained model 133 (S2). In S2, the calculator 11 executes, by the first simulation model 132 using a plurality of processing parameters, a shape simulation of performing substrate processing on a substrate having a specific initial shape. The specific initial shape is included in the shape of the substrate acquired in S1. Initial values of the plurality of processing parameters are predetermined and stored in the storage 13. The initial values of the processing parameter may be determined by the user operating the operation unit 15.

The calculator 11 adjusts the plurality of processing parameters by repeating the shape simulation while changing the values of the plurality of processing parameters so that the predicted shape of the substrate calculated by the shape simulation approaches the specific post-processing shape included in the shape of the substrate acquired in S1. The calculator 11 ends the adjustment of the processing parameters in a state where the predicted shape of the substrate calculated by the shape simulation sufficiently approaches the specific post-processing shape. For example, the calculator 11 calculates an error function representing a difference between the predicted shape obtained by the shape simulation and a specific post-processing shape, and ends the adjustment of the processing parameters when a value of the error function falls within the predetermined range.

Alternatively, in S2, the calculator 11 inputs the plurality of processing parameters and the specific initial shape of the substrate into the trained model 133. The trained model 133 outputs a predicted shape of the substrate according to the input of the processing parameters and the initial shape. The calculator 11 repeats the processing while changing the values of the plurality of processing parameters so that the predicted shape of the substrate output from the trained model 133 approaches a specific post-processing shape. That is, the calculator 11 repeats inputting the changed processing parameters and the specific initial shape into the trained model 133, and the trained model 133 repeats outputting the predicted shape. In this way, the calculator 11 adjusts the plurality of processing parameters.

The calculator 11 ends the adjustment of the processing parameters in a state where the predicted shape of the substrate output from the trained model 133 sufficiently approaches the specific post-processing shape. For example, the calculator 11 calculates an error function representing a difference between the predicted shape output from the trained model 133 and a specific post-processing shape, and ends the adjustment of the processing parameters when the value of the error function falls within the predetermined range. With the processing in S2, the information processing device 1 acquires the values of the plurality of adjusted processing parameters.

The information processing device 1 acquires a predicted shape of the substrate by the first simulation model 132 using the plurality of adjusted processing parameters (S3). In S3, the calculator 11 executes, by the first simulation model 132 using the plurality of adjusted processing parameters, a shape simulation of performing substrate processing on a substrate having a specific initial shape. The first simulation model 132 calculates a predicted shape by the shape simulation. The calculator 11 acquires the calculated predicted shape.

The information processing device 1 acquires a predicted shape of the substrate using the trained model 133 (S4). In S4, the calculator 11 inputs the plurality of adjusted processing parameters and the specific initial shape of the substrate into the trained model 133. The trained model 133 outputs the predicted shape of the substrate according to the input of the processing parameters and the initial shape. The calculator 11 acquires the predicted shape output from the trained model 133.

The specific initial shapes of the substrates used in S2 to S4 are the same. The values of the processing parameters used in S3 and S4 are the same. The first simulation models 132 used in S2 and S3 are the same. The trained models 133 used in S2 and S4 are the same. S3 and S4 may be executed in a reverse order or may be executed in parallel.

Next, the information processing device 1 calculates an error between the predicted shape acquired by the first simulation model 132 and the predicted shape acquired using the trained model 133 (S5). In S5, the calculator 11 calculates the error between the predicted shape acquired in S3 and the predicted shape acquired in S4. For example, the calculator 11 calculates an absolute value or a square of a difference between the predicted shape acquired in S3 and the predicted shape acquired in S4 as an error.

Next, the information processing device 1 determines whether the calculated error is less than a predetermined threshold value (S6). In S6, the calculator 11 compares a predetermined threshold value stored in advance in the storage 13 with the calculated error to determine whether the error is less than the threshold value. If the error is equal to or more than the threshold value (S6: NO), the information processing device 1 determines that the accuracy of prediction of the shape of the substrate using the trained model 133 is insufficient (S7). In S6 and S7, the information processing device 1 may determine that the accuracy is insufficient if the error exceeds the threshold value.

Ideally, the predicted shape acquired by the first simulation model 132 and the predicted shape acquired by using the trained model 133 are required to be the same.

However, compared with the first simulation model 132 that simulates substrate processing, the trained model 133 that outputs a predicted shape without going through a simulation process tends to have less accurate prediction of the post-processing shape of the substrate. With the processing in S1 to S7, the accuracy of prediction using the trained model 133 can be evaluated. Thereafter, the information processing device 1 performs information processing for improving the accuracy of prediction using the trained model 133.

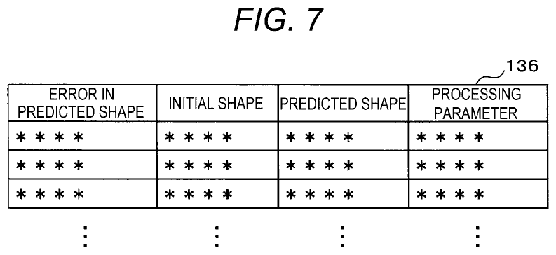

Next, the information processing device 1 records data related to the prediction using the trained model 133 into the error database 136 (S8). FIG. 7 is a conceptual diagram illustrating an example of the contents of the error database 136. The error between the predicted shape obtained by the first simulation model 132 and the predicted shape obtained by the trained model 133, the values of specific initial shapes and a plurality of processing parameters input to the trained model 133, and the predicted shapes output by the trained model 133 are recorded in the error database 136 in an associated manner. In S8, the calculator 11 records, in the error database 136, the error calculated in S5, the specific initial shape acquired in S1, the predicted shape acquired in S4, and the values of the plurality of processing parameters adjusted in S2, in an associated manner. A plurality of data sets, in which errors, initial shapes, predicted shapes, and values of a plurality of processing parameters obtained through past information processing are associated with each other, are recorded in the error database 136.

The information processing device 1 determines whether the specific initial shape is included in a shape range that includes a plurality of initial shapes recorded in the training data 135 (S9). The shape range corresponds to a range of sizes of the initial shapes. In S9, the calculator 11 determines whether the size of the specific initial shape input into the trained model 133 in S4 is included in the range including the sizes of the plurality of initial shapes recorded in the training data 135. For example, the size of the initial shape is a vertical size, a horizontal size, or a height size of the substrate before the substrate processing, or a size of a specific part. If the size of the specific initial shape exceeds the upper limit or is less than the lower limit of the sizes of the plurality of initial shapes recorded in the training data 135, the calculator 11 determines that the shape range that includes the plurality of initial shapes recorded in the training data 135 does not include the specific initial shape. When the size of the specific initial shape falls between the lower limit and the upper limit, the calculator 11 determines that the specific initial shape is included in the shape range. A plurality of shape ranges may be present, each of which defines a lower limit and an upper limit of a size.

Alternatively, the shape range corresponds to a range of a feature indicating a physical structure of an initial shape. The feature indicating the physical structure is, for example, a CD value or an aspect ratio. If the feature of the specific initial shape exceeds the upper limit or is less than the lower limit of the features of the plurality of initial shapes recorded in the training data 135, the calculator 11 determines that the shape range that includes the plurality of initial shapes recorded in the training data 135 does not include the specific initial shape. When the feature of the specific initial shape falls between the lower limit and the upper limit, the calculator 11 determines that the specific initial shape is included in the shape range. A plurality of shape ranges may be present, each of which defines a lower limit and an upper limit of features indicating a physical structure.

When the size of the specific initial shape is different from the size of the initial shape recorded in the training data 135, the initial shape having a size different from the size assumed at a time point of the training of the trained model 133 is input to the trained model 133. Further, when the physical structure of the specific initial shape is different from the physical structure of the initial shape recorded in the training data 135, an initial shape having a physical structure different from the physical structure assumed at a time point of the training of the trained model 133 is input to the trained model 133. Due to this reason, there is a possibility that the error is increased.

If a specific initial shape is included in the shape range that includes the plurality of initial shapes recorded in the training data 135 (S9: YES), the information processing device 1 performs the following processing. The information processing device 1 determines whether a specific initial shape is included in a shape range in which the number of initial shapes included in the plurality of shape ranges that include the plurality of initial shapes recorded in the training data 135 is smaller than the number of initial shapes in other shape ranges (S10). For example, a plurality of ranges of sizes of the initial shapes are predetermined, and the plurality of shape ranges correspond to a plurality of ranges of sizes of the initial shapes. The size of each initial shape recorded in the training data 135 falls within any of the plurality of ranges. Among the plurality of ranges, the range in which the number of initial shapes that include sizes is the smallest is defined as the minimum range.

In S10, the calculator 11 determines whether the size of the specific initial shape input into the trained model 133 in S4 is included in the minimum range. When the size of the specific initial shape is included in the minimum range, the calculator 11 determines that the specific initial shape is included in the shape range that includes a smaller number of initial shapes recorded in the training data 135 than other shape ranges. When the size of the specific initial shape is not included in the minimum range but included in another range, the calculator 11 determines that the specific initial shape is not included in the shape range in which the number of initial shapes included is smaller than the number of initial shapes in the other shape ranges.

Alternatively, a plurality of ranges of features indicating the physical structure of the initial shape are predetermined, and the plurality of shape ranges correspond to a plurality of ranges of features. The feature indicating a physical structure of each initial shape recorded in the training data 135 falls within any of the plurality of ranges. Among the plurality of ranges, a range in which the number of initial shapes that include features is the smallest is defined as a minimum range. In S10, the calculator 11 determines whether the feature indicating the physical structure of the specific initial shape input into the trained model 133 in S4 is included in the minimum range. When the feature indicating the physical structure of the specific initial shape is included in the minimum range, the calculator 11 determines that the specific initial shape is included in the shape range that includes a smaller number of initial shapes recorded in the training data 135 than other shape ranges. When the feature indicating the physical structure of the specific initial shape is not included in the minimum range and is included in another range, the calculator 11 determines that the specific initial shape is not included in the shape range in which the number of initial shapes included is smaller than the number of initial shapes in the other shape ranges.

When the size of the specific initial shape corresponds to a size of an initial shape recorded in a smaller number among sizes of the initial shapes recorded in the training data 135, the number of times of learning using an initial shape equivalent to the specific initial shape is smaller than the number of times of learning using other initial shapes. Similarly, when the physical structure of the specific initial shape corresponds to a physical structure recorded in a smaller number among the physical structures of the initial shape recorded in the training data 135, the number of times of learning using the initial shape equivalent to the specific initial shape is smaller than the number of times of learning using other initial shapes.

Due to this reason, there is a possibility that the error is increased.

If the specific initial shape is not included in the shape range that includes a smaller number of initial shapes recorded in the training data 135 than other shape ranges (S10: NO), the information processing device 1 determines whether data sets the number of which exceeds a predetermined number are recorded in the error database 136 (S11). The predetermined number is stored in advance in the storage 13. In S1i, the calculator 11 determines whether the number of data sets associated with the errors, the initial shape, the predicted shape, and the values of the plurality of processing parameters, which are recorded in the error database 136, exceeds a predetermined number. In S11, the information processing device 1 may determine whether a predetermined number or more of data sets are recorded in the error database 136.

If the specific initial shape is not included in the shape range including the plurality of initial shapes recorded in the training data 135 (S9: NO), the information processing device 1 generates a new initial shape corresponding to the specific initial shape (S12). If a specific initial shape is included in the shape range that includes a smaller number of initial shapes recorded in the training data 135 than other shape ranges (S10: YES), the information processing device 1 also executes the processing in S12. In S12, the calculator 11 generates, as a new initial shape corresponding to the specific initial shape, an initial shape having a size whose change rate with respect to the size of the specific initial shape is a predetermined ratio. Alternatively, the calculator 11 generates, as a new initial shape corresponding to the specific initial shape, an initial shape having a feature whose change rate with respect to the feature indicating the physical structure of the specific initial shape is a predetermined ratio. The predetermined ratio is a ratio included in a predetermined ratio range of −10% to +10% or the like. For example, the calculator 11 randomly generates a plurality of initial shapes each having a size or a feature whose change rate with respect to the size or the feature of the specific initial shape is included in a predetermined ratio range.

The information processing device 1 acquires a predicted shape of the substrate by the first simulation model 132 using the generated new initial shape (S13). In S13, the calculator 11 executes, by the first simulation model 132, shape simulation of performing substrate processing on a substrate having the generated new initial shape. The first simulation model 132 calculates a predicted shape by the shape simulation, and the calculator 11 acquires the calculated predicted shape. The values of the plurality of processing parameters used in the shape simulation are the values of the plurality of processing parameters recorded in the error database 136 in S8. The calculator 11 acquires a predicted shape for each of the plurality of generated processing shapes.

Next, the information processing device 1 updates the training data 135 by adding data including the acquired predicted shape (S14). In S14, the calculator 11 generates a data set in which the predicted shape acquired in S13 is associated with the new initial shape generated in S12 and the values of the plurality of processing parameters used in the shape simulation in S13, as the post-processing shape. The calculator 11 updates the training data 135 by adding the generated data set to the training data 135.

In S12, a new initial shape having a size or a physical structure different from those assumed at the time point when the trained model 133 was trained is generated. In S13, a predicted shape corresponding to the new initial shape is acquired by the shape simulation. In S14, the acquired predicted shape is used as the new post-processing shape, and a data set of the new initial shape, the values of the processing parameters, and the new post-processing shape is added to the training data 135. The training data 135 is updated to include data corresponding to a size or a physical structure different from those assumed at the time point when the trained model 133 was trained. The updated training data 135 can be used to perform learning based on the new size or the new physical structure of the substrate.

Alternatively, in S12, a new initial shape having a small number of sizes or physical structures recorded in the training data 135 is generated. Through S13 and S14, data corresponding to the sizes or physical structures recorded in the training data 135 in a smaller number is added to the training data 135. The training data 135 is updated to include data corresponding to a smaller number of sizes or physical structures. The updated training data 135 may be used to enhance learning based on a specific size or physical structure.

The information processing device 1 determines whether data sets the number of which exceeds a predetermined number are recorded in the error database 136 (S15). In S15, the information processing device 1 may determine whether a predetermined number or more of data sets are recorded in the error database 136. If the data sets the number of which exceeds the predetermined number are recorded in the error database 136 in S11 or S15 (S11: YES or S15: YES), the information processing device 1 acquires a contribution of each processing parameter to the error of the predicted shape based on the error database 136 (S16).

In S16, the calculator 11 calculates the contribution of each processing parameter to the error using the plurality of data sets stored in the error database 136, thereby acquiring the contribution. For example, the calculator 11 performs correlation analysis on the error recorded in the error database 136 and the values of the plurality of processing parameters to calculate the contribution of each processing parameter to the error. For example, the calculator 11 applies SHapley Additive exPlanations (SHAPs) to the plurality of data sets recorded in the error database 136 to calculate the contribution of each processing parameter to the error.

Next, the information processing device 1 specifies processing parameters having a high contribution to the error (S17). In S17, the calculator 11 specifies a predetermined number of processing parameters having high contributions acquired in S16. For example, the calculator 11 specifies one processing parameter having the maximum contribution.

Next, the information processing device 1 generates a new value obtained by changing the value of the specified processing parameter within a predetermined range (S18). In S18, the calculator 11 changes the value of the specified processing parameter within the predetermined range from the value recorded in the error database 136 to generate a new value for the processing parameter. The change rate of the values of the processing parameters falls within a predetermined range, such as −10% to +10%. For example, the calculator 11 randomly generates a plurality of new values obtained by changing the values of the specified processing parameters within the predetermined range.

The information processing device 1 acquires the predicted shape of the substrate by the first simulation model 132 using the new values of the specified processing parameters (S19). In S19, the calculator 11 executes a shape simulation by the first simulation model 132 using the values of the plurality of processing parameters that include the new values of the specified processing parameters. The values of processing parameters other than the specified processing parameters are stored in the error database 136. The first simulation model 132 calculates a predicted shape by the shape simulation, and the calculator 11 acquires the calculated predicted shape. The initial shape used in the shape simulation is an initial shape recorded in the error database 136 in association with the values of the specified processing parameters. The calculator 11 acquires a predicted shape for each of the plurality of new values of the processing parameters.

Next, the information processing device 1 updates the training data 135 by adding data that includes the acquired predicted shape (S20). In S20, the calculator 11 generates a data set in which the predicted shape acquired in S19 is associated with the values of the plurality of processing parameters, including the new values of the processing parameters generated in S18, and the initial shape used in S19, as the post-processing shape. The calculator 11 updates the training data 135 by adding the generated data set to the training data 135.

The training data 135 is updated to increase the number of data sets with different values of the processing parameters having a high contribution to errors. The learning in which the values of the processing parameters are different can be increased by retraining the trained model 133 using the updated training data 135.

If no data sets the number of which exceeds the predetermined number are recorded in the error database 136 in S15 (S15: NO), or after S20 is ended, the information processing device 1 performs retraining of the trained model 133 (S21). In S21, the calculator 11 inputs the initial shape and the plurality of processing parameters recorded in the updated training data 135 into the trained model 133. The trained model 133 performs calculations according to the inputs of the initial shape and processing parameters, and outputs the predicted shape. The calculator 11 adjusts the parameters of the calculations of the trained model 133 so as to reduce an error between the predicted shape output from the trained model 133 and the post-processing shape associated with the input initial shape and the input processing parameters.

The calculator 11 repeats the processing using the plurality of data sets recorded in the training data 135 to adjust the parameters of the trained model 133, thereby performing the retraining. For example, the adjusted final parameters are stored in the storage 13.

When the trained model 133 is retrained using the updated training data 135, the error between the predicted shape output from the trained model 133 and the predicted shape obtained by the first simulation model 132 may be reduced. For example, retraining based on the new size or the new physical structure of the substrate may be performed by using the updated training data 135, and errors caused by differences in the size or physical structure of the initial shape may be reduced. For example, retraining based on the size or physical structure of a small number of initial shapes may be performed by using the updated training data 135, and errors caused by the small number of sizes or physical structures of the initial shapes may be reduced. For example, the learning in which the values of the processing parameters having high contributions to errors are different can be increased through the retraining using the updated training data 135, and errors affected by the processing parameters can be reduced.

If no data sets the number of which exceeds the predetermined number are recorded in the error database 136 in S11 (S11: NO), or after S21 is ended, the information processing device 1 ends the information processing.

If the error is less than the threshold value in S6 (S6: YES), the information processing device 1 determines that the accuracy of prediction of the shape of the substrate using the trained model 133 is sufficient (S22). In S6 and S22, the information processing device 1 may determine that the accuracy is sufficient if the error is equal to or less than the threshold value.

Next, the information processing device 1 acquires a predicted shape of the substrate by the second simulation model 134 (S23). In S23, the calculator 11 executes the shape simulation by the second simulation model 134. The initial shape of the substrate and the values of the plurality of processing parameters used in the shape simulation are the initial shape and the values of the plurality of processing parameters used in S3. The second simulation model 134 calculates a predicted shape by the shape simulation, and the calculator 11 acquires the calculated predicted shape. The calculator 11 acquires a plurality of predicted shapes by the plurality of second simulation models 134.

The information processing device 1 calculates an error between the predicted shape acquired by the second simulation model 134 and the predicted shape acquired using the trained model 133 (S24). In S24, the calculator 11 calculates an error between each predicted shape acquired in S24 and the predicted shape acquired in S4. For example, the calculator 11 calculates an absolute value of the difference between the predicted shapes or the square of the difference as an error.

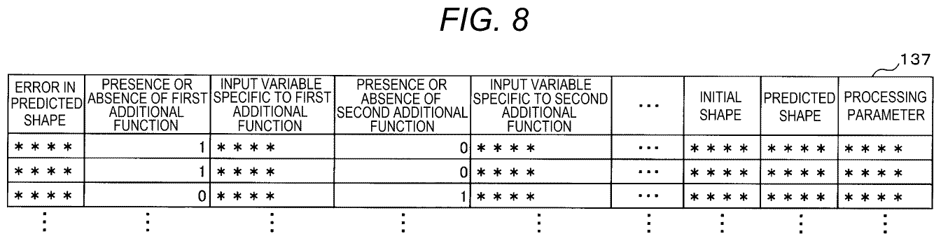

Next, the information processing device 1 records data related to the prediction using the trained model 133 and the prediction using the second simulation model 134 into the model database 137 (S25). FIG. 8 is a conceptual diagram illustrating an example of the contents of the model database 137. The error between the predicted shape obtained by the second simulation model 134 and the predicted shape obtained by the trained model 133 is recorded in the model database 137. The presence or absence of each additional function, such as the first additional function and the second additional function, is recorded in association with the error in the predicted shape in the model database 137. The presence or absence of a certain additional function indicates whether the additional function is included in the second simulation model 134. For example, each second simulation model 134 includes one additional function, and does not include other additional functions. In the example shown in FIG. 8, [1] indicates that a certain additional function is included, and [0] indicates that the additional function is not included.

The values of input variables specific to the respective additional functions are recorded in association with errors in predicted shapes in the model database 137. The specific initial shapes and values of the plurality of processing parameters input into the trained model 133 and predicted shapes output from the trained model 133 are recorded in association with errors in the predicted shapes in the model database 137. In S25, the calculator 11 records, in the model database 137, the errors calculated in S24, the specification of each second simulation model 134, the initial shapes and the values of the plurality of processing parameters used in S4, and the predicted shapes acquired in S4, in association with one another. The model database 137 records a plurality of data sets in which errors obtained through past information processing, the presence or absence of each additional function, values of input variables specific to each additional function, initial shapes, predicted shapes, and values of the plurality of processing parameters are associated with each other.

The information processing device 1 determines whether the number of pieces of data with large errors related to any of the additional functions recorded in the model database 137 exceeds a predetermined number (S26). In S26, the calculator 11 specifies an error exceeding a predetermined threshold value from the errors recorded in the model database 137. Further, the calculator 11 measures, for each additional function, the number of pieces of data associated with each additional function and including errors exceeding a predetermined threshold value, and determines whether the number of pieces of measured data exceeds a predetermined number. The calculator 11 may specify errors that are equal to or more than a predetermined threshold value, and may determine whether the number of pieces of data is equal to or more than a predetermined number.

If the number of pieces of data with large errors related to a certain additional function exceeds the predetermined number (S26: YES), the information processing device 1 specifies the second simulation model 134 including the additional function (S27). In S27, the calculator 11 specifies the second simulation model 134 including a specific additional function from the plurality of second simulation models 134, when the number of pieces of data associated with any specific additional function and including errors exceeding the predetermined threshold value exceeds the predetermined number. When the number of pieces of data including errors exceeding the predetermined threshold value for the plurality of additional functions exceeds the predetermined number, the calculator 11 specifies the second simulation model 134 that includes the additional function for which the number of pieces of data including errors exceeding the predetermined threshold value is the maximum.

The information processing device 1 acquires the predicted shape of the substrate by the specified second simulation model 134 (S28). In S28, the specified calculator 11 executes a shape simulation by the second simulation model 134. The calculator 11 performs a shape simulation using the initial shape of the substrate and the values of the plurality of processing parameters stored in the model database 137 in association with errors exceeding the predetermined threshold value and specific additional functions. The second simulation model 134 calculates a predicted shape by the shape simulation, and the calculator 11 acquires the calculated predicted shape. The calculator 11 performs a plurality of times of shape simulations to acquire a plurality of predicted shapes. For example, the shape simulation is performed for the number of pieces of data associated with the errors exceeding the predetermined threshold value and the specific additional functions.

Next, the information processing device 1 updates the training data 135 by adding data that includes the acquired predicted shape (S29). In S29, the calculator 11 generates a data set in which the predicted shape acquired in S28 is associated with the initial shape of the substrate and the values of the plurality of processing parameters used in S28, as the post-processing shape. The calculator 11 updates the training data 135 by adding the generated data set to the training data 135. The training data 135 is updated to increase the data set related to a specific additional function. The specific additional function is a function that increases the error between the predicted shape obtained through the shape simulation including the additional function and the predicted shape obtained through the first simulation model 132.

Next, the information processing device 1 performs retraining of the trained model 133 (S30). In S30, the calculator 11 inputs the initial shape and the plurality of processing parameters recorded in the updated training data 135 into the trained model 133. The trained model 133 outputs the predicted shape, and the calculator 11 adjusts the parameters of the calculation of the trained model 133 so as to reduce an error between the predicted shape and the post-processing shape associated with the input initial shape and the input processing parameters. The calculator 11 repeats the processing using the plurality of data sets recorded in the training data 135 to adjust the parameters of the trained model 133, thereby performing the retraining. For example, the adjusted final parameters are stored in the storage 13.

When the trained model 133 is retrained using the updated training data 135, it is possible to perform learning for reflecting certain physical effects, which are not considered in the first simulation model 132, in the predicted shape output by the trained model 133. The trained model 133 after the retraining outputs a predicted shape that reflects a specific physical effect according to the additional function. The trained model 133 can output a predicted shape closer to reality than the predicted shape obtained by the first simulation model 132. Therefore, the accuracy of the substrate shape prediction using the trained model 133 is improved.

Next, the information processing device 1 updates the first simulation model 132 to the specified second simulation model 134 (S31). In S31, the calculator 11 updates the first simulation model 132 to the second simulation model 134 specified in S27. Thereafter, a shape simulation including the additional function is performed using the updated first simulation model 132. Accordingly, the accuracy of the shape simulation is improved, and the error between the predicted shape of the substrate based on the shape simulation and the predicted shape output from the retrained trained model 133 are prevented from being increased.

If the number of pieces of data with large errors related to any of the additional functions recorded in the model database 137 does not exceed the predetermined number (S26: NO), or after S31 is ended, the information processing device 1 ends the information processing. The information processing device 1 repeats the information processing of S1 to S31 as appropriate.

As described in detail above, in the present embodiment, the information processing device 1 acquires a predicted shape of the substrate by the first simulation model 132, acquires a predicted shape by using the trained model 133, and calculates the error between the predicted shapes. Based on the calculated error, the information processing device 1 determines the accuracy of the substrate shape prediction using the trained model 133. In this way, the information processing device 1 can evaluate the accuracy of the substrate shape prediction using the trained model 133.

When the accuracy of the prediction using the trained model 133 is insufficient, the information processing device 1 updates the training data 135 and causes the trained model 133 to be retrained so as to reduce the error. When the accuracy of the prediction using the trained model 133 is sufficient, the information processing device 1 updates the training data 135 and causes the trained model 133 to be retrained so as to reflect a specific physical effect according to the additional function in the predicted shape. In this way, the accuracy of the substrate shape prediction using the trained model 133 is improved. Compared with the shape simulation using a simulation model, information processing using a trained model often has lower computation costs. The shape of the substrate can be predicted with high accuracy at low computation cost by using the trained model 133 in which the prediction accuracy is improved. This improvement integrates the abstract evaluation process into a practical application for semiconductor manufacturing, where the retrained trained model outputs optimized processing parameters that are transmitted as control signals to a substrate processing apparatus, adjusting operational conditions like plasma power or chamber pressure to achieve desired substrate shapes, thereby minimizing over-etching, ensuring critical dimensions, and increasing production throughput in fabrication facilities producing logic chips or memory devices.

The disclosure is not limited to contents of the above-described embodiment, and various modifications may be made within the scope described in the following claims. In other words, embodiments obtained by combining technical means appropriately changed within the scope indicated in the claims are also included in the technical scope of the disclosure.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

1. A non-transitory computer-readable storage medium storing a computer program that, when executed by a computer, causes the computer to execute a method comprising:
adjusting, by using a simulation model that simulates substrate processing using a plurality of parameters related to a condition of the substrate processing, or a trained model that outputs a predicted shape obtained by predicting a shape of a substrate after processing according to inputs of the plurality of parameters and an initial shape of the substrate, the plurality of parameters such that the predicted shape becomes a specific shape,
acquiring a predicted shape by simulating the substrate processing by the simulation model using the plurality of parameters after the adjustment and a specific initial shape of the substrate,
acquiring a predicted shape using the trained model according to the plurality of parameters after the adjustment and the specific initial shape,
calculating an error between the predicted shape acquired by the simulation model and the predicted shape acquired using the trained model,
determining accuracy of the prediction using the trained model based on the error, and
based on the determined accuracy, retraining the trained model and using the retrained trained model to output optimized processing parameters as control signals to a substrate processing apparatus, the control signals adjusting operational conditions.

2. The non-transitory computer-readable storage medium according to claim 1, wherein
the computer is caused to execute processing of:
comparing the specific initial shape with an initial shape recorded in training data used for training of the trained model when the accuracy of the prediction using the trained model is insufficient,
generating a new initial shape corresponding to the specific initial shape when the specific initial shape is not included in a shape range including a plurality of initial shapes recorded in the training data, or when the specific initial shape is included in a shape range in which the number of initial shapes included is smaller than the number of initial shapes in other shape ranges among a plurality of shape ranges including any one of the plurality of initial shapes recorded in the training data,
acquiring a new predicted shape by the simulation model using the new initial shape,
updating the trained data by adding the new initial shape and the new predicted shape to the training data, and
retraining the trained model using the updated training data.

3. The non-transitory computer-readable storage medium according to claim 1, wherein
the computer is caused to execute processing of:
specifying a parameter having a high contribution to the error from the plurality of parameters when the accuracy of the prediction using the trained model is insufficient,
changing a value of the specified parameter within a predetermined range, and acquiring a new predicted shape by the simulation model using the parameter whose value is changed,
updating, by adding values of the plurality of parameters including the changed value and the new predicted shape to training data used for training of the trained model, the training data, and
retraining the trained model using the updated training data.

4. The non-transitory computer-readable storage medium according to claim 1, wherein
the computer is caused to execute processing of:
acquiring a predicted shape by a plurality of second simulation models each having a function related to a specific physical effect, which is not included in the simulation model,
calculating an error between the predicted shape acquired by the simulation model and the predicted shape acquired by the plurality of second simulation models,
recording data that is associated with the function and includes the error,
acquiring a plurality of new predicted shapes by the second simulation model including the specific function when the number of pieces of recorded data associated with a specific function and including the error exceeding a predetermined threshold value exceeds a predetermined number,
updating, by adding the plurality of new predicted shapes to training data used for training of the trained model, the training data, and
retraining the trained model using the updated training data.

5. The non-transitory computer-readable storage medium according to claim 4, wherein
the computer is caused to execute processing of updating the simulation model to the second simulation model including the specific function.

6. The non-transitory computer-readable storage medium according to claim 1, wherein the plurality of parameters include at least one of gas type, gas flow rate, voltage, frequency, pressure, or temperature in a process chamber.

7. The non-transitory computer-readable storage medium according to claim 1, wherein the trained model is implemented using a neural network.

8. The non-transitory computer-readable storage medium according to claim 1, wherein the error is calculated as an absolute value of a difference or a square of a difference between the predicted shapes.

9. An information processing method comprising:
adjusting, by using a simulation model that simulates substrate processing using a plurality of parameters related to a condition of the substrate processing, or a trained model that outputs a predicted shape obtained by predicting a shape of a substrate after processing according to inputs of the plurality of parameters and an initial shape of the substrate, the plurality of parameters such that the predicted shape becomes a specific shape,
acquiring a predicted shape by simulating the substrate processing by the simulation model using the plurality of parameters after the adjustment and a specific initial shape of the substrate,
acquiring a predicted shape using the trained model according to the plurality of parameters after the adjustment and the specific initial shape,
calculating an error between the predicted shape acquired by the simulation model and the predicted shape acquired using the trained model,
determining accuracy of the prediction using the trained model based on the error; and
based on the determined accuracy, retraining the trained model and using the retrained trained model to output optimized processing parameters as control signals to a substrate processing apparatus, the control signals adjusting operational conditions.

10. The information processing method according to claim 9, further comprising:
storing the error in an error database associated with the specific initial shape and the plurality of parameters when the accuracy is insufficient.

11. The information processing method according to claim 9, wherein the simulation model is a first simulation model, and the method further comprises using a plurality of second simulation models each including an additional function related to a physical effect not in the first simulation model.

12. The information processing method according to claim 11, wherein the additional function calculates an influence on the predicted shape caused by at least one of an electric external field, film damage, by-product dependence, temperature effect, or particle diffusion.

13. The information processing method according to claim 9, further comprising updating the simulation model to include a specific additional function when a number of errors exceeding a threshold associated with the additional function exceeds a predetermined number.

14. An information processing device comprising:
circuitry configured to: adjust, by using a simulation model that simulates substrate processing using a plurality of parameters related to a condition of the substrate processing, or a trained model that outputs a predicted shape obtained by predicting a shape of a substrate after processing according to inputs of the plurality of parameters and an initial shape of the substrate, the plurality of parameters such that the predicted shape becomes a specific shape,
acquire a predicted shape by simulating the substrate processing by the simulation model using the plurality of parameters after the adjustment and a specific initial shape of the substrate,
acquire a predicted shape using the trained model according to the plurality of parameters after the adjustment and the specific initial shape,
calculate an error between the predicted shape acquired by the simulation model and the predicted shape acquired using the trained model,
determine accuracy of the prediction using the trained model based on the error, and
based on the determined accuracy, retrain the trained model and use the retrained trained model to output optimized processing parameters as control signals to a substrate processing apparatus, the control signals adjusting operational conditions.

15. The information processing device according to claim 14, further comprising memory storing training data including initial shapes, processing parameters, and post-processing shapes.

16. The information processing device according to claim 14, wherein the circuitry is further configured to generate a new initial shape based on comparison with recorded initial shapes in training data when the accuracy is insufficient.

17. The information processing device according to claim 14, further comprising an error database for recording errors exceeding a threshold, associated with initial shapes and processing parameters.

18. The information processing device according to claim 14, further comprising a model database for recording errors between predicted shapes from the simulation model and second simulation models with additional functions.

19. The information processing device according to claim 14, wherein the circuitry is further configured to retrain the trained model using updated training data including new predicted shapes from second simulation models.

20. The information processing device according to claim 14, wherein the substrate processing includes etching or film formation on a semiconductor wafer.
